(19) United States
(12) Patent Application Publication
(10) Pub. No.: US 2025/0225928 A1
(43) Pub. Date: Jul. 10, 2025

(54) DISPLAY PANEL

(71) Applicant: Wuhan China Star Optoelectronics Semiconductor Display Technology Co., Ltd., Wuhan, Hubei (CN)

(72) Inventors: Xuanyun WANG, Wuhan, Hubei (CN); Chao DAI, Wuhan, Hubei (CN); Fang QIN, Wuhan, Hubei (CN)

(73) Assignee: Wuhan China Star Optoelectronics Semiconductor Display Technology Co., Ltd., Wuhan, Hubei (CN)

(21) Appl. No.: 17/623,633

(22) PCT Filed: Dec. 21, 2021
(86) PCT No.: PCT/CN2021/140207

§ 371 Date: Dec. 29, 2021

(30) Foreign Application Priority Data
Dec. 17, 2021 (CN) 202111555323.3

(51) Int. Cl. G09G 3/3233; G09G 3/32

(52) U.S. Cl. CPC G09G 3/3233; G09G 3/32; G09G 2310/08; G09G 2320/0247; G09G 2330/021

(57) ABSTRACT

A display panel is provided by the present application. The display panel includes a plurality of sub-pixels, wherein each sub-pixel includes a driving circuit. The driving circuit includes a light-emitting device, a driving transistor, a first transistor, a first capacitor, a second transistor, and a third transistor. A characteristic of the oxide of thin film transistor is used to suppress a gate electrical potential change of the driving transistor within a frame time after the first transistor is turned off by electrically connecting a drain electrode of the first transistor and a gate electrode of the driving transistor.

### FIELD OF INVENTION

The present application relates to display technologies, and more particularly, to a display panel.

### BACKGROUND OF INVENTION

With a development of multimedia, display devices have become more and more important. Correspondingly, the requirements for various types of display devices are becoming higher and higher, especially in a field of smart phones. Ultra-high frequency drive displays, low-power drive displays, and low-frequency drive displays are all current and future development needs.

P-channel metal oxide semiconductor field effect transistors (PMOS) is widely used as transistors in display devices, and low-temperature polysilicon (LTPS) is widely used in a mobile phone field. However, one of the fatal weaknesses of LTPS is that a leakage current is large, especially in the low-frequency display, there is a serious problem of flicker.

In view of this, the currently technology needs to be improved.

### SUMMARY OF INVENTION

The present application provides a display panel to realize a pixel circuit design for ultra-low frequency and ultra-low power consumption display.

In a first aspect, the present application provides
a light-emitting device and a driving transistor, wherein the light-emitting device and the driving transistor are connected in series between a first power supply voltage and a second power supply voltage;
a first transistor, wherein a gate electrode of the first transistor receives a first control signal, a drain electrode of the first transistor is electrically connected to a gate electrode of the driving transistor, and wherein the first transistor is an oxide film transistor
a first capacitor, wherein one terminal of the first capacitor is electrically connected to the gate electrode of the driving transistor, and another terminal of the first capacitor is connected to the first power supply voltage;
a second transistor, wherein a gate electrode of the second transistor receives a second control signal, a source electrode of the second transistor is electrically connected to a source electrode of the first transistor, a drain electrode of the second transistor is connected to a drain electrode of the driving transistor; and
a third transistor, wherein a gate electrode of the third transistor receives the third control signal, a source electrode of the third transistor receives a first reset signal, and a drain electrode of the third transistor is electrically connected to the source electrode of the first transistor.

Optionally, in some embodiments of the present application, the first transistor is a P-type transistor or an N-type transistor.

Optionally, in some embodiments of the present application, the driving transistor, the second transistor, and the third transistor are low temperature polysilicon thin film transistors.

Optionally, in some embodiments of the present application, the driving circuit further includes a fourth transistor, and wherein a gate electrode of the fourth transistor receives the second control signal, and a source electrode of the fourth transistor receives the data signal, and a drain electrode of the fourth transistor is electrically connected to a source electrode of the driving transistor.

Optionally, in some embodiments of the present application, the fourth transistor is a low temperature polysilicon thin film transistor.

Optionally, in some embodiments of the present application, the driving circuit further includes a fifth transistor and a sixth transistor, and wherein a gate electrode of the fifth transistor and a gate electrode of the sixth transistor both receive a light-emitting control signal, and wherein a source electrode of the fifth transistor receives the first power supply voltage, a drain electrode of the fifth transistor is electrically connected to the source electrode of the driving transistor, and wherein a drain electrode of the sixth transistor is electrically connected to an anode of the light-emitting device, and a source electrode of the sixth transistor is electrically connected to the drain electrode of the driving transistor.

Optionally, in some embodiments of the present application, the second transistor and the sixth transistor have a single-gate structure.

Optionally, in some embodiments of the present application, the fifth transistor and the sixth transistor are low temperature polysilicon thin film transistors.

Optionally, in some embodiments of the present application, the driving circuit further includes a seventh transistor, and wherein a gate electrode of the seventh transistor receives the second control signal, a source electrode of the seventh transistor receives a second reset signal, and a drain electrode of the seventh transistor is electrically connected to an anode of the light-emitting device.

Optionally, in some embodiments of the present application, the seventh transistor is a low temperature polysilicon thin film transistor.

Optionally, in some embodiments of the present application, the first control signal is the light emission control signal.

Optionally, in some embodiments of the present application, the driving circuit further includes a second capacitor, one terminal of the second capacitor is electrically connected to the gate electrode of the driving transistor, and another terminal of the second capacitor receives the second control signal.

Optionally, in some embodiments of the present application, the electrical potential of the first power supply voltage is greater than the electrical potential of the second power supply voltage.

Optionally, in some embodiments of the present application, the light-emitting device is an organic light-emitting diode.

Optionally, in some embodiments of the present application, the driving circuits of the plurality of sub-pixels are arranged in an array, and wherein the driving circuits of two adjacent columns of sub-pixels are arranged in a mirror-symmetrical structure.

Optionally, in some embodiments of the present application, the display panel further includes:
a first conductive channel layer including a polysilicon active layer and a first electrode plate of the first capacitor;
a first metal layer including a gate electrode of a polysilicon thin film transistor and a second electrode plate of the first capacitor;
a second metal layer including a gate electrode of an oxide thin film transistor;
a third metal layer including a source electrode of the polysilicon thin film transistor, a drain electrode of the polysilicon thin film transistor, a source electrode of the oxide thin film transistor, and a drain electrode of the oxide thin film transistor; and
a second conductive channel layer including an oxide semiconductor active layer.

Optionally, in some embodiments of the present application, the sub-pixels positioned in a same row are sequentially divided into a plurality of pairs of sub-pixels in a sequence, and wherein each pair of sub-pixels has a common boundary,
wherein in the second conductive channel layer, the active layers of the first transistors in each pair of sub-pixels are arranged opposite to and close to the common boundary of each pair of sub-pixels, and wherein the active layers of the first transistors of each pair of sub-pixels are parallel to the common boundary of each pair of sub-pixels.

Optionally, in some embodiments of the present application, the first metal layer further includes a first electrode plate of the second capacitor, and wherein the second conductive channel layer further includes a second electrode plate of the second capacitor.

Optionally, in some embodiments of the present application, the sub-pixels positioned in a same row are sequentially divided into a plurality of pairs of sub-pixels in a sequence, and wherein each pair of sub-pixels has a common boundary;
wherein in the second conductive channel layer, the second electrode plate of the second capacitor and the active layer of the first transistor are positioned in a same axial direction, and wherein the second capacitors in each pair of sub-pixels are oppositely and close to the common boundary of each pair of sub-pixels.

The present application also provides a display panel including a plurality of sub-pixels, each sub-pixel includes a driving circuit, and wherein the driving circuit includes:
a light-emitting device and a driving transistor, wherein the light-emitting device and the driving transistor are connected in series between a first power supply voltage and a second power supply voltage;
a first transistor, wherein a gate electrode of the first transistor receives a first control signal, a drain electrode of the first transistor is electrically connected to a gate electrode of the driving transistor, and wherein the first transistor is an oxide film transistor
a first capacitor, wherein one terminal of the first capacitor is electrically connected to the gate electrode of the driving transistor, and another terminal of the first capacitor is connected to the first power supply voltage;
a second transistor, wherein a gate electrode of the second transistor receives a second control signal, a source electrode of the second transistor is electrically connected to a source electrode of the first transistor, a drain electrode of the second transistor is connected to a drain electrode of the driving transistor; and
a third transistor, wherein a gate electrode of the third transistor receives the third control signal, a source electrode of the third transistor receives a first reset signal, and a drain electrode of the third transistor is electrically connected to the source electrode of the first transistor;
wherein the driving transistor, the second transistor, and the third transistor are low temperature polysilicon thin film transistors.

Optionally, in some embodiments of the present application, the first transistor is a P-type transistor or an N-type transistor.

Optionally, in some embodiments of the present application, the driving circuit further includes a fourth transistor, and wherein a gate electrode of the fourth transistor receives the second control signal, and a source electrode of the fourth transistor receives the data signal, and a drain electrode of the fourth transistor is electrically connected to a source electrode of the driving transistor.

Optionally, in some embodiments of the present application, the fourth transistor is a low temperature polysilicon thin film transistor.

Optionally, in some embodiments of the present application, the driving circuit further includes a fifth transistor and a sixth transistor, and wherein a gate electrode of the fifth transistor and a gate electrode of the sixth transistor both receive a light-emitting control signal, and wherein a source electrode of the fifth transistor receives the first power supply voltage, a drain electrode of the fifth transistor is electrically connected to the source electrode of the driving transistor, and wherein a drain electrode of the sixth transistor is electrically connected to an anode of the light-emitting device, and a source electrode of the sixth transistor is electrically connected to the drain electrode of the driving transistor.

Optionally, in some embodiments of the present application, the second transistor and the sixth transistor have a single-gate structure.

Optionally, in some embodiments of the present application, the fifth transistor and the sixth transistor are low temperature polysilicon thin film transistors.

Optionally, in some embodiments of the present application, the driving circuit further includes a seventh transistor, and wherein a gate electrode of the seventh transistor receives the second control signal, and a source electrode of the seventh transistor receives a second reset signal, a drain electrode of the seventh transistor is electrically connected to an anode of the light-emitting device.

Optionally, in some embodiments of the present application, the seventh transistor is a low temperature polysilicon thin film transistor.

Optionally, in some embodiments of the present application, the first control signal is the light emission control signal.

Optionally, in some embodiments of the present application, the driving circuit further includes a second capacitor, one terminal of the second capacitor is electrically connected to the gate electrode of the driving transistor, and another terminal of the second capacitor receives the second control signal.

Optionally, in some embodiments of the present application, an electrical potential of the first power supply voltage is greater than an electrical potential of the second power supply voltage.

Optionally, in some embodiments of the present application, the light-emitting device is an organic light-emitting diode.

Optionally, in some embodiments of the present application, the driving circuits of the plurality of sub-pixels are arranged in an array, and wherein the driving circuits of two adjacent columns of sub-pixels are arranged in a mirror-symmetrical structure.

Optionally, in some embodiments of the present application, the display panel further includes:
a first conductive channel layer including a polysilicon active layer and a first electrode plate of the first capacitor;
a first metal layer including a gate electrode of a polysilicon thin film transistor and a second electrode plate of the first capacitor;
a second metal layer including a gate electrode of an oxide thin film transistor;
a second conductive channel layer including an oxide semiconductor active layer; and
a third metal layer including a source electrode of the polysilicon thin film transistor, a drain electrode of the polysilicon thin film transistor, a source electrode of the oxide thin film transistor, and a drain electrode of the oxide thin film transistor.

Optionally, in some embodiments of the present application, the sub-pixels positioned in a same row are sequentially divided into a plurality of pairs of sub-pixels in a sequence, and wherein each pair of sub-pixels has a common boundary,
wherein in the second conductive channel layer, the active layers of the first transistors in each pair of sub-pixels are arranged opposite to and close to the common boundary of each pair of sub-pixels, and wherein the active layers of the first transistors of each pair of sub-pixels are parallel to the common boundary of each pair of sub-pixels.

Optionally, in some embodiments of the present application, the first metal layer further includes a first electrode plate of the second capacitor, and wherein the second conductive channel layer further includes a second electrode plate of the second capacitor.

Optionally, in some embodiments of the present application, the sub-pixels positioned in a same row are sequentially divided into a plurality of pairs of sub-pixels in a sequence, and wherein each pair of sub-pixels has a common boundary;
wherein in the second conductive channel layer, the second electrode plate of the second capacitor and the active layer of the first transistor are positioned in a same axial direction, and wherein the second capacitors in each pair of sub-pixels are oppositely and close to the common boundary of each pair of sub-pixels.

The present application provides a display panel. The display panel includes a plurality of sub-pixels, wherein each sub-pixel includes a driving circuit including a light-emitting device, a driving transistor, a first transistor, a first capacitor, a second transistor, and a third transistor. A low leakage characteristics of the oxide thin film transistor is used to suppress a change of the gate potential of the driving transistor within one frame time, and to improve an electrically potential stability of the gate electrode of the driving transistor after the first transistor is turned off, the light-emitting device starts to emit light, and after the first transistor is turned off by electrically connecting a drain electrode of the first transistor and a gate electrode of the driving transistor, electrically connecting a source electrode of the third transistor to a source electrode of the first transistor, and disposing an oxide thin film transistor as the first transistor. Therefore, the leakage of the oxide thin film transistor is controlled by the oxide thin film transistor to realize the effects of high image quality display, low frequency and low power consumption. As a result, the display within the display period of one frame of the picture is more uniform when the display panel is operating at a low display frequency, thereby avoiding flicker.

### DESCRIPTION OF FIGURES

In order to explain the technical solutions in the embodiments of the present application more clearly, the following will briefly introduce the figures needed in the description of the embodiments. Obviously, the figures in the following description are only some embodiments of the present application. For those skilled in the art, without inventive steps, other figures can be obtained based on these figures.

FIG. 1 is a schematic structural diagram of a first driving circuit of a display panel provided by the present application.

FIG. 2 is a time sequence diagram of the display panel described in FIG. 1.

FIG. 3 is a schematic structural diagram of a second driving circuit of the display panel provided by the present application.

FIG. 4 is a time sequence diagram of the display panel described in FIG. 3.

FIG. 5 is a schematic structural diagram of a third driving circuit of the display panel provided by the present application.

FIG. 6 is a time sequence diagram of the display panel described in FIG. 5.

FIG. 7 is a schematic diagram of a symmetrical structure of the sub-pixels of the display panel provided by the present application.

FIG. 8 is a schematic diagram of a symmetrical structure of a third metal layer of the sub-pixels of the display panel provided by the present application.

### DETAILED DESCRIPTION OF EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

In the description of this application, it should be understood that the terms “first” and “second” are only used for descriptive purposes, and cannot be understood as indicating or implying relative importance or implicitly indicating the number of indicated technical features. Therefore, the features defined as “first” and “second” may explicitly or implicitly include one or more features, and therefore cannot be understood as a limitation of the present application.

The transistors used in all the embodiments of the present application can be thin film transistors or field effect transistors or other devices with the same characteristics. Since a source electrode and a drain electrode of the transistor used here are symmetrical, the source electrode and the drain electrode can be interchanged. In the embodiments of the present application, in order to distinguish the two electrodes of the transistor other than the gate electrode, one of the electrodes is called the source electrode and the other is called the drain electrode. According to the form in the figure, it is stipulated that the middle terminal of the switching transistor is the gate electrode, the signal input terminal is the source electrode, and the output terminal is the drain electrode. In addition, the transistors used in the embodiments of the present application may include P-type transistors and/or N-type transistors. The P-type transistor is turned on when the gate electrode is at a low electrical potential and turned off when the gate electrode is at a high electrical potential, and the N-type transistor is turned on when the gate electrode is at the high electrical potential, and N-type transistor is turned off when the gate electrode is at the low electrical potential. According to the form in the figure, it is stipulated that the middle terminal of the transistor is the gate electrode, a signal input terminal is the source electrode, and the output terminal is the drain electrode.

The present application provides a display panel, which will be described in detail below. It should be noted that the description order of the following embodiments is not intended to limit a preferred order of the embodiments of the present application.

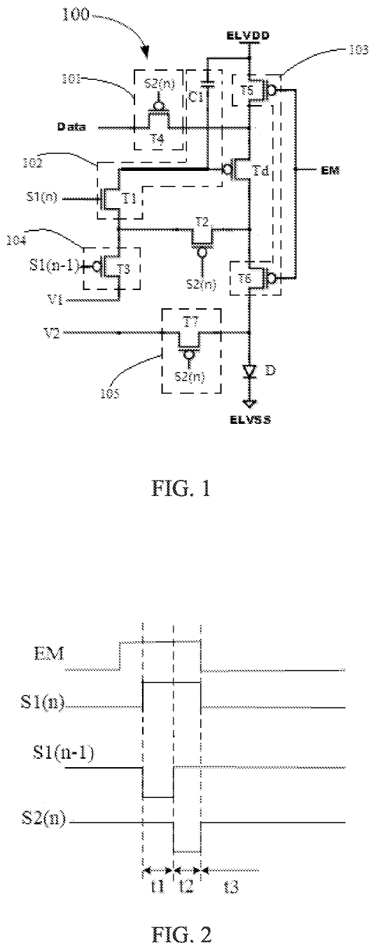

It should be noted that, since the source electrode and the drain electrode of the transistor used in the present application are symmetrical, the source electrode and the drain electrode can be interchanged. Please refer to FIG. 1. FIG. 1 is a schematic structural diagram of a first driving circuit of a display panel provided by the present application. The present application provides a display panel, which includes a plurality of sub-pixels, and wherein each sub-pixel includes a driving circuit 100. The driving circuit 100 includes a light-emitting device D, a driving transistor Td, a writing module 101, a compensation module 102, a light-emitting control module 103, and a first reset module 104. It should be noted that the light-emitting device D can be a mini light-emitting diode, a micro light-emitting diode or an organic-light emitting diode.

The light-emitting device D and the driving transistor Td are connected in series between the first power supply voltage VDD and the second power supply voltage VSS. The source electrode and the drain electrode of the driving transistor Td are connected in series between the first power supply voltage and the second power supply voltage.

The writing module 101 receives the second control signal S2(n) and the data signal Da, and is electrically connected to the source electrode of the driving transistor Td. The writing module 101 is configured to write the data signal Da into the source electrode of the driving transistor Td under a control of the second control signal S2(n).

The compensation module 102 receives the first control signal S1(n) and the first power supply voltage VDD, and is electrically connected to a drain electrode of the driving transistor Td and a gate electrode of the driving transistor Td. The compensation module 102 is configured to compensate the threshold voltage of the driving transistor Td under the control of the first control signal S1(n). Specifically, the compensation module 102 includes a first transistor T1, a second transistor T2, and a first capacitor C1. A gate electrode of the first transistor T1 receives the first control signal S1(n). A drain electrode of the first transistor T1 and one terminal of the first capacitor C1 is electrically connected to a gate electrode of the driving transistor Td. A gate electrode of the second transistor T2 receives the second control signal S2(n). A source electrode of the second transistor T2 is electrically connected to the source electrode of the first transistor T1. A source electrode of the second transistor T2 is electrically connected to the drain electrode of the driving transistor Td. Another terminal of the first capacitor C1 receives the first power supply voltage VDD. The first transistor T1 is an oxide thin film transistor. Of course, it is understandable that the compensation module 102 can also be formed by using a plurality of transistors and a capacitor in series.

The light-emitting control module 103 is receives the light-emitting control signal EM, and is connected in series to the light-emitting circuit. The light-emitting control module 103 is configured to control the light-emitting circuit to be turned on or off under a control of the light-emitting control signal EM. It should be noted that the present application only needs to ensure that the light-emitting control module 103 and the light-emitting device D are connected in series to the light-emitting circuit. The display panel shown in FIG. 1 only illustrates a specific position of the light-emitting control module 103 and the light-emitting device D. That is, the light-emitting control module 103 and the light-emitting device D can be connected in series at any position on the light-emitting circuit.

The first reset module 104 receives a third control signal S1(n−1) and a first reset signal V1, and is electrically connected to the source electrode of the first transistor T1. The first reset module 104 is configured to reset an electrical potential of the gate electrode of the driving transistor Td under a control of the third control signal S1(n−1). The first reset module 104 includes a third transistor T3. A gate electrode of the third transistor T3 receives the third control signal S1(n−1). A source electrode of the third transistor T3 receives the first reset signal V1. A drain electrode of the second transistor T2 is electrically connected to the source electrode of the first transistor T1. Of course, it is understandable that the first reset module 104 can also be formed by using a plurality of transistors in series.

In the display panel provided by the present application, a low leakage characteristics of the oxide thin film transistor is used to suppress a change of the gate potential of the driving transistor within one frame time, and to improve an electrically potential stability of the gate electrode of the driving transistor after the first transistor is turned off, the light-emitting device starts to emit light, and after the first transistor is turned off by electrically connecting a drain electrode of the first transistor and a gate electrode of the driving transistor, electrically connecting a source electrode of the third transistor to a source electrode of the first transistor, and disposing an oxide thin film transistor as the first transistor. Therefore, the leakage of the oxide thin film transistor is controlled by the oxide thin film transistor to realize the effects of high image quality display, low frequency and low power consumption.

Further, please continue to refer to FIG. 1, the driving circuit further includes a second reset module 105. The second reset module 105 receives the second control signal S2(n) and the second reset signal V2, and is electrically connected to an anode of a light-emitting device D. The second reset module 105 is configured to reset the electrical potential of the anode of the light-emitting device D under the control of the second control signal S2(n).

In the present application, the second reset module 105 can be used to reset the electrical potential of the anode of the light-emitting device D, to prevent the residual charge of the anode of the light-emitting device D from affecting a light-emitting brightness of the light-emitting device D.

In some embodiments, please refer to FIG. 1, FIG. 1 is a schematic structural diagram of a first driving circuit of a display panel provided by the present application. The writing module 101 includes a fourth transistor T4.

A gate electrode of the fourth transistor T4 receives the second control signal S2(n). A source electrode of the fourth transistor T4 receives a data signal Da. A drain electrode of the fourth transistor T4 is electrically connected to the source electrode of the driving transistor Td. Of course, it is understandable that the writing module 101 can also be formed by using a plurality of transistors in series.

In some embodiments, the light emission control module 103 includes a fifth transistor T5 and a sixth transistor T6. A gate electrode of the fifth transistor T5 and a gate electrode of the sixth transistor T6 both receives the light-emitting control signal EM. A source electrode of the fifth transistor T5 receives the first power supply voltage VDD. A drain electrode of the fifth transistor T5 is electrically connected to the source electrode of the driving transistor Td. A drain electrode of the sixth transistor T6 is electrically connected to the source electrode of the driving transistor Td. A drain electrode of the sixth transistor T6 is electrically connected to an anode of the light-emitting device D. A source electrode of the sixth transistor T6 is electrically connected to the drain electrode of the driving transistor Td. Of course, it is understandable that the light emission control module 103 can also be formed by using a plurality of transistors in series.

In some embodiments, the second transistor and the sixth transistor have a single-gate structure. The second transistor and the sixth transistor adopt a single-gate structure, which can control the driving circuit by the single-gate structure, wherein the single-gate structure has less leakage than a double-gate structure, which is beneficial to reduce a power consumption of the driving circuit.

Of course, it is understandable that in the display panel provided in the present application, the light-emitting control module 103 may include 3, 4 or more light-emitting control units. Each light-emitting control unit is serially connected to a light-emitting circuit. A plurality of light-emitting control units can receive a same lighting control signal EM or different lighting control signals EM. In addition, it can be understood that each light-emitting control unit can also be formed by using a plurality of transistors in series.

In some embodiments, the second reset module 105 includes a seventh transistor T7. A gate electrode of the seventh transistor T7 receives the second control signal S2(n). A source electrode of the seventh transistor T7 receives a second reset signal V2. A drain electrode of the seventh transistor T7 is electrically connected to the anode of the light-emitting device D. Of course, it is understandable that the second reset module 105 can also be formed by using a plurality of transistors in series.

In this embodiment, the first control signal S1(n) is set as a light-emitting control signal EM. By setting the first control signal as the light-emitting control signal, the arrangement of driving signals can be reduced to facilitate a realization of a narrow frame of the screen.

The display panel provided by the present application adopts a display panel with an 8T1C (8 transistors and 1 capacitor) structure to control the light-emitting device D, which uses fewer components, has a simple and stable structure, and saves costs.

In the present application, both the first power supply voltage VDD and the second power supply voltage VSS are configured to output a preset voltage value. In addition, in the present application, an electrical potential of the first power supply voltage VDD is greater than an electrical potential of the second power supply voltage VSS. Specifically, the electrical potential of the second power supply voltage VSS may be an electrical potential of a ground terminal. Of course, it is understandable that the electrical potential of the second power supply voltage VSS may also be other.

In the present application, the driving transistor TD, the second transistor, the third transistor, the fourth transistor, the fifth transistor, the sixth transistor, and the seventh transistor may be one or more of low temperature polysilicon thin film transistors, oxide thin film transistors, or amorphous silicon thin film transistors. In addition, the transistors in the display panel provided by the present application may also be P-type transistors or N-type transistors. Further, the transistors in the display panel provided by the present application can be set to be a same type of transistors, to avoid an influence of a difference between different types of transistors on the display panel.

It should be noted that, in the following embodiments of the present application, the first transistor is a P-type transistor, and the driving transistor, the second transistor, the third transistor, the fourth transistor, the fifth transistor, the sixth transistor, and the seventh transistor are N-type transistors as examples, but they cannot be understood as a limitation of the present application.

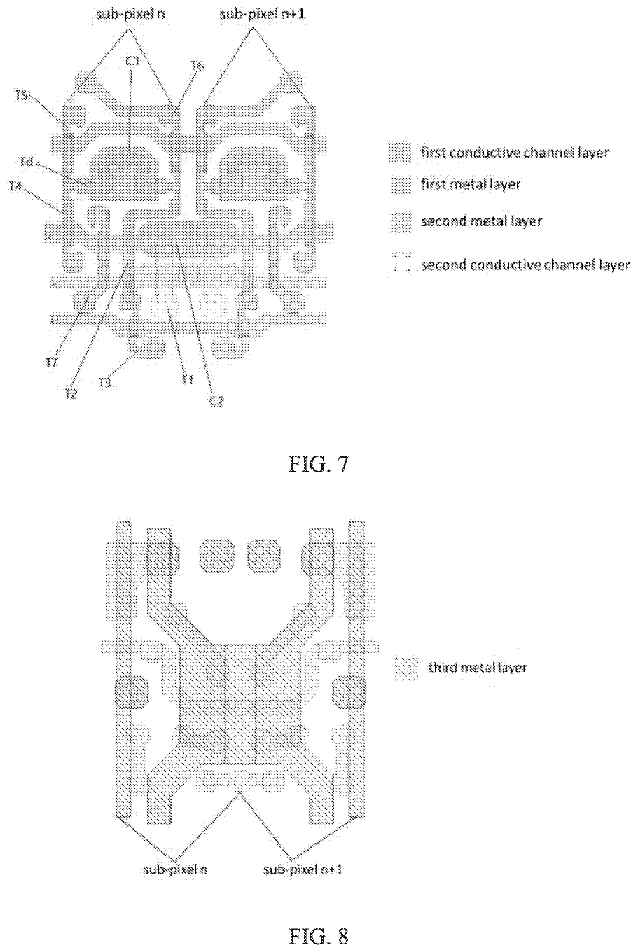

Please refer to FIGS. 7 and 8. FIG. 7 is a schematic diagram of a symmetrical structure of the sub-pixels of the display panel provided by the present application. FIG. 8 is a schematic diagram of a symmetrical structure of a third metal layer of the sub-pixels of the display panel provided by the present application. In some embodiments, the driving circuits of the plurality of sub-pixels are arranged in an array, and wherein the driving circuits of two adjacent columns of sub-pixels are arranged in a mirror-symmetrical structure. As shown in FIG. 7 and FIG. 8, the driving circuits of sub-pixel n and sub-pixel n+1 are mirror-symmetrical. In the present application, the driving circuits of two adjacent columns of sub-pixels are arranged in a mirror-symmetrical structure, thereby providing space for improvement of pixel density, which is conducive to realize high-pixel-density panel design.

In some embodiments, the display panel further includes: a first conductive channel layer, a first metal layer, a second metal layer, a third metal layer, and a second conductive channel layer.

The first conductive channel layer includes a polysilicon active layer and a first electrode plate of the first capacitor C1. The first metal layer includes a gate electrode of a polysilicon thin film transistor and a second electrode plate of the first capacitor C1. The second metal layer includes a gate electrode of an oxide thin film transistor. The third metal layer includes a source electrode and a drain electrode of the polysilicon thin film transistor, and a source electrode of the oxide thin film transistor and a drain electrode of the oxide thin film transistor. The second conductive channel layer includes an oxide semiconductor active layer. In the present application, the first capacitor is made by the first conductive channel and the first metal layer, which can further provide space for the improvement of pixel density and facilitate the design of larger high pixel density panels.

In some embodiments, the sub-pixels in a same row are divided into a plurality of pairs of sub-pixels in sequence, and each pair of sub-pixels has a common boundary.

In the second conductive channel layer, the active layers of the first transistors T1 in each pair of sub-pixels are arranged opposite to and close to the common boundary of each pair of sub-pixels, and wherein the active layers of the first transistors T1 of each pair of sub-pixels are parallel to the common boundary of each pair of sub-pixels. That is, because the first transistor is an oxide thin film transistor, the active layer of the first transistor in each pair of sub-pixels are arranged close to facilitate an insulation arrangement, which can reduce a cost and space of the insulation arrangement, and is conducive to achieving high-pixel-density panel design. In addition, the active layer of the first transistor in each pair of sub-pixels is parallel to the common boundary of each pair of sub-pixels, so that the control signal lines of the gates of the first transistors T1 positioned on a same row can be uniformly arranged.

That is, in some embodiments, the driving transistor TD, the second transistor, the third transistor, the fourth transistor, the fifth transistor, the sixth transistor, and the seventh transistor may be low temperature polysilicon thin film transistors. The active layers of the driving transistor TD, the second transistor, the third transistor, the fourth transistor, the fifth transistor, the sixth transistor, and the seventh transistor are provided in the first conductive channel layer. The gate electrodes of the driving transistor TD, the second transistor, the third transistor, the fourth transistor, the fifth transistor, the sixth transistor, and the seventh transistor are provided on the first metal layer. The first transistor is an oxide thin film transistor. The active layer of the first transistor is provided on the second conductive channel layer. The gate electrode of the first transistor is provided on the second metal layer.

Please refer to FIG. 1 and FIG. 2. FIG. 2 is a time sequence diagram of the display panel described in FIG. 1. A combination of the light-emitting control signal EM, the first control signal S1(n), the second control signal S2(n), and the third control signal S1(n−1) sequentially corresponds to a reset phase t1, a compensation phase t2, and a light-emitting phase t3. That is, within one frame time, the driving control sequence of the display panel provided by the present application includes the reset phase t1, the compensation phase t2, and the light-emitting phase t3.

In the reset phase t1, the third control signal S1(n−1) is at a low electrical potential. The first control signal S1(), the second control signal S2(n), and the light-emitting control signal EM are all at high electrical potential. At this time, the second transistor T2, the fourth transistor T4, the fifth transistor T5, the sixth transistor T6, and the seventh transistor T7 are all turned off. The first transistor T1 and the third transistor T3 are turned on. The first reset signal V1 is output to the gate electrode of the driving transistor Td through the third transistor and the first transistor. The electrical potential of the gate electrode of the driving transistor Td is reset to the electrical potential of the first reset signal V1.

In the compensation phase t2, the second control signal S2(n) is at the low electrical potential. The first control signal S1(n), the third control signal S1(n−1) and the light-emitting control signal EM are all high electrical potentials. At this time, the third transistor T3, the fifth transistor T5, and the sixth transistor T6 are all turned off. The first transistor T1, the second transistor T2, and the fourth transistor T4 are turned on. The data signal Da is written to the gate electrode of the driving transistor Td through the second transistor, the driving transistor Td, the first transistor, and the fourth transistor.,

The driving transistor Td is turned off, and the electrical potential of the gate electrode of the driving transistor Td no longer rises when the electrical potential of the gate electrode of the driving transistor Td is charged to Vdata−Vth. The first capacitor C1 stores the electrical potential of the gate electrode of the driving transistor Td.

At the same time, since the second control signal S2(n) is at the low electrical potential, the seventh transistor T7 is turned on. The electrical potential of the anode of the light-emitting device D is reset to the electrical potential of the second reset signal V2. Therefore, it is ensured that the light-emitting device D does not emit light during the compensation phase t2.

In the light-emitting phase t3, the first control signal S1(n) and the light-emitting control signal EM are both at the low electrical potential, and the second control signal S2(n) and the third control signal S1(n−1) are at the high electrical potential. At this time, the first transistor T1, the second transistor T2, the third transistor T3, the fourth transistor T4, and the seventh transistor T7 are all turned off. The driving transistor Td, the sixth transistor T6, and the fifth transistor T5 are all turned on. The driving transistor Td generates a driving current corresponding to the data signal Da by the electrical potential of the gate electrode. The driving current flows to the light-emitting device D through the turned-on driving transistor Td, the fifth transistor T5, and the sixth transistor T6, and drives the light-emitting device D to emit light.

Further, please refer to FIG. 3, FIG. 3 is a schematic structural diagram of a second driving circuit of the display panel provided by the present application. A difference from the display panel shown in FIG. 1 is that the driving transistor, the first transistor, the second transistor, the third transistor, the fourth transistor, the fifth transistor, the sixth transistor, and the seventh transistor in the present application are all N-type transistors for illustration, but it cannot be understood as a limitation of the present application.

Moreover, in the present embodiment, the first control signal S1(n) and the light-emitting control signal are independent control signals.

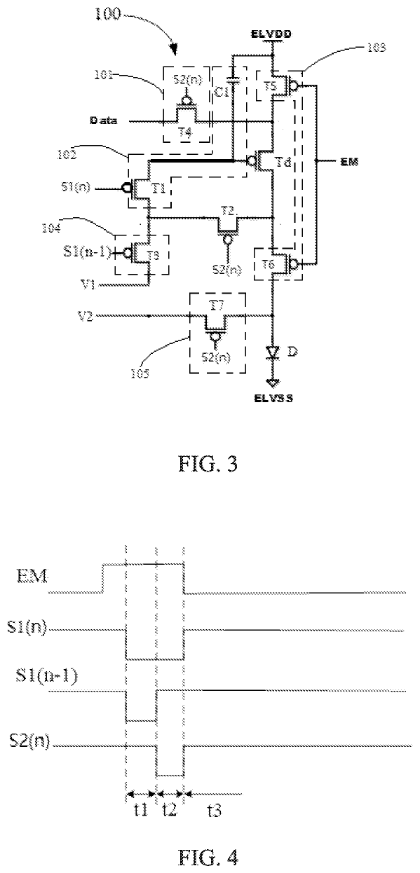

Please refer to FIG. 3 and FIG. 4. FIG. 4 is a time sequence diagram of the display panel described in FIG. 3. A combination of the light-emitting control signal EM, the first control signal S1(n), the second control signal S2(n), and the third control signal S1(n−1) sequentially corresponds to a reset phase t1, a compensation phase t2, and a light-emitting phase t3. That is, within one frame time, the driving control sequence of the display panel provided by the present application includes the reset phase t1, the compensation phase t2, and the light-emitting phase t3.

In the reset phase t1, the first control signal S1(n) and the third control signal S1(n−1) are at a low electrical potential. The second control signal S2(n) and the light-emitting control signal EM are both at high electrical potential. At this time, the second transistor T2, the fourth transistor T4, the fifth transistor T5, the sixth transistor T6, and the seventh transistor T7 are all turned off. The first transistor T1 and the third transistor T3 are turned on. The first reset signal V1 is output to the gate electrode of the driving transistor Td through the third transistor and the first transistor. The electrical potential of the gate electrode of the driving transistor Td is reset to the electrical potential of the first reset signal V1.

In the compensation phase t2, the first control signal S1(n) and the second control signal S2(n) are at a low electrical potential. The third control signal S1(n−1) and the light-emitting control signal EM are both at a high electrical potential. At this time, the third transistor T3, the fifth transistor T5, and the sixth transistor T6 are all turned off. The first transistor T1, the second transistor T2, and the fourth transistor T4 are turned on. The data signal Da is written to the gate electrode of the driving transistor Td through the second transistor, the driving transistor Td, the first transistor, and the fourth transistor. The driving transistor Td is turned off, and the electrical potential of the gate electrode of the driving transistor Td no longer rises when the electrical potential of the gate electrode of the driving transistor Td is charged to Vdata-Vth. The first capacitor C1 stores the electrical potential of the gate electrode of the driving transistor Td.

At the same time, since the second control signal S2(n) is at the low electrical potential, the seventh transistor T7 is turned on. The electrical potential of the anode of the light-emitting device D is reset to the electrical potential of the second reset signal V2. Therefore, it is ensured that the light-emitting device D does not emit light during the compensation phase t2.

In the light-emitting phase t3, the light-emitting control signal EM is at the low electrical potential, and the first control signal S1(n), the second control signal S2(n), and the third control signal S1(n−1) are at the high electrical potential. At this time, the first transistor T1, the second transistor T2, the third transistor T3, the fourth transistor T4, and the seventh transistor T7 are all turned off. The driving transistor Td, the sixth transistor T6, and the fifth transistor T5 are all turned on. The driving transistor Td generates a driving current corresponding to the data signal Da by the electrical potential of the gate electrode. The driving current flows to the light-emitting device D through the turned-on driving transistor Td, the fifth transistor T5, and the sixth transistor T6, and drives the light-emitting device D to emit light.

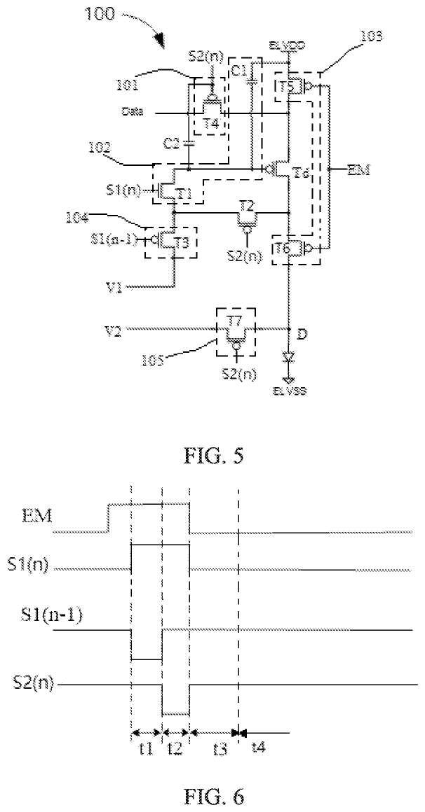

Further, please refer to FIG. 5 and FIG. 7. FIG. 5 is a schematic structural diagram of a third driving circuit of the display panel provided by the present application. A difference from the display panel shown in FIG. 1 is that, in this embodiment, the driving circuit further includes a second capacitor C2. One terminal of the second capacitor C2 is electrically connected to the gate electrode of the driving transistor Td, and another terminal of the second capacitor C2 is connected to the first control signal S1(n).

It is understandable that in the actual panel manufacturing process, it is difficult to avoid some parasitic capacitances. The electrical potential of the drain electrode of the first transistor is coupled to a lower electrical potential due to a coupling effect of a parasitic capacitance, thereby affecting the gate electrical potential of the driving transistor Td. In this embodiment, by setting the second capacitor C2, the electrical potential of the drain electrode of the first transistor can be reverse-coupled, so that the electrical potential of the drain electrode of the first transistor is as consistent as possible with the electrical potential of the gate electrode of the driving transistor Td. Thus, the electrical potential stability of the gate electrode of the driving transistor Td can be further ensured. The specific coupling process will be described in detail in the following embodiments.

In some embodiments, the sub-pixels located in the same row are sequentially divided into a plurality of pairs of sub-pixels, each pair of sub-pixels having a common boundary. In the second conductive channel layer, the second electrode plate of the second capacitor and the active layer of the first transistor are positioned in a same axial direction. The second capacitors in each pair of sub-pixels are arranged oppositely and close to the common boundary of each pair of sub-pixels. The second capacitors in each pair of sub-pixels are arranged in close proximity to facilitate an insulation arrangement, which can reduce cost and space of the insulation arrangement, and facilitates the realization of a high-pixel-density panel design. In addition, arranging the second electrode plate of the second capacitor and the active layer of the first transistor in a same axial direction can reduce a design space and facilitate a realization of the high-pixel-density panel design.

In some embodiments, the first metal layer further includes the first electrode plate of the second capacitor. The second conductive channel layer further includes the second electrode plate of the second capacitor. In the present application, the second metal layer and the second conductive channel layer are fabricated into the second capacitor, which can further provide space for the improvement of pixel density and facilitate the design of larger high pixel density panels.

In addition, in this embodiment, another terminal of the second capacitor C2 is connected to the first control signal for emitting-light, which can simplify the wiring in the display panel. Of course, in other embodiments of the present application, another terminal of the second capacitor C2 can also be connected to other control signals to achieve reverse coupling to the electrical potential of the drain electrode of the first transistor.

It should be noted that, in some embodiments of the present application, the driving control time sequence of the display panel shown in FIG. 5 is the same as the driving control time sequence of the display panel shown in FIG. 1. That is, the driving control sequence of the display panel shown in FIG. 5 includes a reset phase t1, a compensation phase t2, and a light-emitting phase t3.

The only difference is that when the driving control time sequence of the display panel changes from the compensation phase t2 to the light-emitting phase t3, capacitive coupling will occur in the display panel due to the setting of the second capacitor C2.

It can be understood that after the data signal Da is written, the first control signal S1(n) changes from the high electrical potential to the low electrical potential. The electrical potential of the drain electrode of the first transistor is coupled to an electrical potential lower than the electrical potential of the gate electrode of the driving transistor Td.

In the subsequent light-emitting stage, due to a leakage of the first transistor, the electrical potential of the gate electrode of the driving transistor Td will continue to drop.

Therefore, in the embodiment, the light-emitting control signal EM changes from the high electrical potential to the low electrical potential. Due to the coupling effect of the second capacitor C2, the electrical potential of the drain electrode of the first transistor is pulled up. Further, by designing a capacitance value of the second capacitor C2, the electrical potential of the drain electrode of the first transistor can be pulled up to be substantially consistent with the electrical potential of the gate electrode of the driving transistor Td. Therefore, a electrical potential stability of the gate electrode of the driving transistor Td is improved, and a light-emitting brightness of the light-emitting device D is prevented from changing within one frame.

In some embodiments of the present application, please refer to FIG. 6, which is a time sequence diagram of the light-emitting device driving circuit shown in FIG. 5. A difference from the driving control time sequence shown in FIG. 2 is that, in this embodiment, the driving control time sequence of the display panel further includes a capacitive coupling phase t4. That is, within one frame time, the driving control sequence of the display panel provided by the present application includes a reset phase t1, a compensation phase t2, a capacitive coupling phase t4, and a light-emitting phase t3.

For the working process of the display panel in the reset phase t1 and the compensation phase t2, please refer to the above-mentioned embodiment, which will not be repeated here.

In the capacitive coupling phase t4, the second control signal S2(n) and the third control signal S1(n−1) are both at a high electrical potential. The first control signal S1(n) and the light-emitting control signal EM change from the high electrical potential to a low electrical potential. At this time, the first transistor T1, the second transistor T2, the third transistor T3, the fourth transistor T4, and the seventh transistor T7 are all turned off. The fifth transistor T5 and the sixth transistor T6 are switched from off to on.

It can be understood that, the first control signal S1(n) changes from the high electrical potential to the low electrical potential after the data signal Da is written. The electrical potential of the drain electrode of the first transistor is coupled to an electrical potential lower than the electrical potential of the gate electrode of the driving transistor Td. In a subsequent light-emitting stage, due to a leakage of the first transistor, the electrical potential of the gate electrode of the driving transistor Td will continue to drop.

Therefore, in the capacitive coupling phase t4 of the present application, the light-emitting control signal EM changes from a high electrical potential to a low electrical potential. Due to the coupling effect of the second capacitor C2, the electrical potential of the drain electrode of the first transistor is pulled up. Further, by designing the capacitance value of the second capacitor C2, the electrical potential of the drain electrode of the first transistor can be pulled up to be substantially consistent with the electrical potential of the gate electrode of the driving transistor Td. Therefore, an electrical potential stability of the gate electrode of the driving transistor Td is improved, and a light-emitting brightness of the light-emitting device D is prevented from changing within one frame.

It should be noted that, in the capacitive coupling stage t4, the light-emitting device D will also emit light when the light-emitting control signal EM changes from a high electrical potential to a low potential, However, since the time of the capacitive coupling stage t4 is very short, an overall light-emitting brightness of the light-emitting device D is not affected.

In the light-emitting phase t3, the first control signal S1(n) and the light-emitting control signal EM are both at a low electrical potential, and the second control signal S2(n) and the third control signal S1(n−1) are at a high electrical potential. At this time, the first transistor, the second transistor, the third transistor, the fourth transistor, and the seventh transistor are all turned off. The driving transistor Td, the fifth transistor T5, and the sixth transistor T6 are all turned on. The driving transistor Td generates a driving current corresponding to the data signal Da by the electrical potential of the gate electrode. The driving current flows to the light-emitting device D through the turned-on fifth transistor T5, the driving transistor Td, and the sixth transistor T6, and drives the light-emitting device D to emit light.

The above is a detailed introduction to a display panel provided by the embodiments of the present application. Specific examples are used in this article to illustrate the principles and implementations of the present application. The description of the above embodiments is only used to help understand the method and core idea of the present application. At the same time, for those skilled in the art, according to the idea of the present application, there will be changes in the specific implementation and the scope of application. In summary, the content of this specification should not be construed as a limitation to the present application.

What is claimed is:

1. A display panel comprising a-plurality of sub-pixels, wherein each sub-pixel comprises a driving circuit, and wherein the driving circuit comprises:
a light-emitting device and a driving transistor, wherein the light-emitting device and the driving transistor are connected in series between a first power supply voltage and a second power supply voltage;
a first transistor, wherein a gate electrode of the first transistor receives a first control signal, a drain electrode of the first transistor is electrically connected to a gate electrode of the driving transistor, and wherein the first transistor is an oxide film transistor;
a first capacitor, wherein one terminal of the first capacitor is electrically connected to the gate electrode of the driving transistor, and another terminal of the first capacitor is connected to the first power supply voltage;
a second transistor, wherein a gate electrode of the second transistor receives a second control signal, a source electrode of the second transistor is electrically connected to a source electrode of the first transistor, a drain electrode of the second transistor is connected to a drain electrode of the driving transistor; and
a third transistor, wherein a gate electrode of the third transistor receives the third control signal, a source electrode of the third transistor receives a first reset signal, and a drain electrode of the third transistor is electrically connected to the source electrode of the first transistor.

2. The display panel according to claim 1, wherein the driving circuit further comprises a fourth transistor, and wherein a gate electrode of the fourth transistor receives the second control signal, a source electrode of the fourth transistor receives a data signal, and a drain electrode of the fourth transistor is electrically connected to a source electrode of the driving transistor.

3. The display panel according to claim 2, wherein the driving circuit further comprises a fifth transistor and a sixth transistor, and wherein a gate electrode of the fifth transistor and a gate electrode of the sixth transistor both receive a light-emitting control signal, and wherein a source electrode of the fifth transistor receives the first power supply voltage, a drain electrode of the fifth transistor is electrically connected to the source electrode of the driving transistor, and wherein a drain electrode of the sixth transistor is electrically connected to an anode of the light-emitting device, and a source electrode of the sixth transistor is electrically connected to the drain electrode of the driving transistor.

4. The display panel according to claim 3, wherein the driving circuit further comprises a seventh transistor, and wherein a gate electrode of the seventh transistor receives the second control signal, a source electrode of the seventh transistor receives a second reset signal, and a drain electrode of the seventh transistor is electrically connected to the anode of the light-emitting device.

5. The display panel according to claim 4, wherein the driving circuit further comprises a second capacitor, one terminal of the second capacitor is electrically connected to the gate electrode of the driving transistor, and another terminal of the second capacitor receives the second control signal.

6. The display panel according to claim 5, wherein the driving circuits of the plurality of sub-pixels are arranged in an array, and wherein the driving circuits of two adjacent columns of sub-pixels are arranged in a mirror-symmetrical structure.

7. The display panel according to claim 6, wherein the display panel further comprises:
a first conductive channel layer comprising a polysilicon active layer and a first electrode plate of the first capacitor;
a first metal layer comprising a gate electrode of a polysilicon thin film transistor and a second electrode plate of the first capacitor;
a second metal layer comprising a gate electrode of an oxide thin film transistor;
a second conductive channel layer comprising an oxide semiconductor active layer; and
a third metal layer comprising a source electrode of the polysilicon thin film transistor, a drain electrode of the polysilicon thin film transistor, a source electrode of the oxide thin film transistor, and a drain electrode of the oxide thin film transistor.

8. The display panel according to claim 7, wherein the sub-pixels positioned in a same row are sequentially divided into a plurality of pairs of sub-pixels in a sequence, and wherein each pair of sub-pixels has a common boundary;
wherein in the second conductive channel layer, the active layers of the first transistors in each pair of sub-pixels are arranged opposite to and close to the common boundary of each pair of sub-pixels, and wherein the active layers of the first transistors of each pair of sub-pixels are parallel to the common boundary of each pair of sub-pixels.

9. The display panel according to claim 7, wherein the first metal layer further comprises a first electrode plate of the second capacitor, and wherein the second conductive channel layer further comprises a second electrode plate of the second capacitor.

10. The display panel according to claim 9, wherein the sub-pixels positioned in a same row are sequentially divided into a plurality of pairs of sub-pixels in a sequence, and wherein each pair of sub-pixels has a common boundary;
wherein in the second conductive channel layer, the second electrode plate of the second capacitor and the active layer of the first transistor are positioned in a same axial direction, and wherein the second capacitors in each pair of sub-pixels are oppositely and close to the common boundary of each pair of sub-pixels.

11. A display panel comprising a plurality of sub-pixels, wherein each sub-pixel comprises a driving circuit, and wherein the driving circuit comprises:
a light-emitting device and a driving transistor, wherein the light-emitting device and the driving transistor are connected in series between a first power supply voltage and a second power supply voltage;
a first transistor, wherein a gate electrode of the first transistor receives a first control signal, a drain electrode of the first transistor is electrically connected to a gate electrode of the driving transistor, and wherein the first transistor is an oxide film transistor;
a first capacitor, wherein one terminal of the first capacitor is electrically connected to the gate electrode of the driving transistor, and another terminal of the first capacitor is connected to the first power supply voltage;
a second transistor, wherein a gate electrode of the second transistor receives a second control signal, a source electrode of the second transistor is electrically connected to a source electrode of the first transistor, a drain electrode of the second transistor is connected to a drain electrode of the driving transistor; and
a third transistor, wherein a gate electrode of the third transistor receives the third control signal, a source electrode of the third transistor receives a first reset signal, and a drain electrode of the third transistor is electrically connected to the source electrode of the first transistor;
wherein the driving transistor, the second transistor, and the third transistor are low temperature polysilicon thin film transistors.

12. The display panel according to claim 11, wherein the driving circuit further comprises a fourth transistor, and wherein a gate electrode of the fourth transistor receives the second control signal, and a source electrode of the fourth transistor receives a data signal, and a drain electrode of the fourth transistor is electrically connected to a source electrode of the driving transistor.

13. The display panel according to claim 12, wherein the driving circuit further comprises a fifth transistor and a sixth transistor, and wherein a gate electrode of the fifth transistor and a gate electrode of the sixth transistor both receive a light-emitting control signal, and wherein a source electrode of the fifth transistor receives the first power supply voltage, a drain electrode of the fifth transistor is electrically connected to the source electrode of the driving transistor, and wherein a drain electrode of the sixth transistor is electrically connected to an anode of the light-emitting device, and a source electrode of the sixth transistor is electrically connected to the drain electrode of the driving transistor.

14. The display panel according to claim 13, wherein the driving circuit further comprises a seventh transistor, and wherein a gate electrode of the seventh transistor receives the second control signal, and a source electrode of the seventh transistor receives a second reset signal, a drain electrode of the seventh transistor is electrically connected to the anode of the light-emitting device.

15. The display panel according to claim 14, wherein the driving circuit further comprises a second capacitor, one terminal of the second capacitor is electrically connected to the gate electrode of the driving transistor, and another terminal of the second capacitor receives the second control signal.

16. The display panel according to claim 15, wherein the driving circuits of the plurality of sub-pixels are arranged in an array, and wherein the driving circuits of two adjacent columns of sub-pixels are arranged in a mirror-symmetrical structure.

17. The display panel according to claim 16, wherein the display panel further comprises:
a first conductive channel layer comprising a polysilicon active layer and a first electrode plate of the first capacitor;
a first metal layer comprising a gate electrode of a polysilicon thin film transistor and a second electrode plate of the first capacitor;
a second metal layer comprising a gate electrode of an oxide thin film transistor;
a second conductive channel layer comprising an oxide semiconductor active layer; and
a third metal layer comprising a source electrode of the polysilicon thin film transistor, a drain electrode of the polysilicon thin film transistor, a source electrode of the oxide thin film transistor, and a drain electrode of the oxide thin film transistor.

18. The display panel according to claim 17, wherein the sub-pixels positioned in a same row are sequentially divided into a plurality of pairs of sub-pixels in a sequence, and wherein each pair of sub-pixels has a common boundary;
wherein in the second conductive channel layer, the active layers of the first transistors in each pair of sub-pixels are arranged opposite to and close to the common boundary of each pair of sub-pixels, and wherein the active layers of the first transistors of each pair of sub-pixels are parallel to the common boundary of each pair of sub-pixels.

19. The display panel according to claim 17, wherein the first metal layer further comprises a first electrode plate of the second capacitor, and wherein the second conductive channel layer further comprises a second electrode plate of the second capacitor.

20. The display panel according to claim 19, wherein the sub-pixels positioned in a same row are sequentially divided into a plurality of pairs of sub-pixels in a sequence, and wherein each pair of sub-pixels has a common boundary;
wherein in the second conductive channel layer, the second electrode plate of the second capacitor and the active layer of the first transistor are positioned in a same axial direction, and wherein the second capacitors in each pair of sub-pixels are oppositely and close to the common boundary of each pair of sub-pixels.
